(19) United States
(12) Patent Application Publication
(10) Pub. No.: US 2010/0237897 A1
(43) Pub. Date: Sep. 23, 2010

(54) OVERCURRENT DETECTING CIRCUIT AND POWER SUPPLY DEVICE

(76) Inventors: Hiroyuki Kikuta, Kyoto (JP); Norihiro Kawagishi, Shizuoka (JP); Yuichi Ohkubo, Gunma (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/724,715

(22) Filed: Mar. 16, 2010

(30) Foreign Application Priority Data
Mar. 19, 2009 (JP) 2009-068280

(51) Int. Cl. G01R 31/36

(52) U.S. Cl. 324/771

(57) ABSTRACT

An overcurrent detecting circuit includes a comparison transistor, a constant current source circuit, and a comparison circuit. The comparison transistor includes a gate and a drain respectively connected to a gate and a drain of a main transistor provided in a power circuit. The comparison transistor is used for comparison with the main transistor when a voltage higher than a power supply voltage is applied to the gate of the main transistor and the gate of the comparison transistor during the operation of the power circuit. The constant current source circuit generates a constant current and supplies the constant current to the comparison transistor. The comparison circuit compares a source voltage of the comparison transistor with a source voltage of the main transistor and outputs a voltage indicating the comparison result.

### CROSS-REFERENCE TO RELATED APPLICATIONS

This application is based on and claims priority under 35 U.S.C. §119 from Japanese Patent Application No. 2009-068280 filed on Mar. 19, 2009, the disclosure of which is incorporated by reference herein.

### RELATED ART

1. Field of the Disclosure

The disclosure relates to a relates to an overcurrent detecting circuit and a power supply device and, more particularly, to an overcurrent detecting circuit that detects an overcurrent flowing through a main transistor of a power circuit and a power supply device including the overcurrent detecting circuit.

2. Description of the Related Art

Japanese Patent Application Laid-Open (JP-A) No. 2007-244128 discloses an overcurrent detecting circuit that detects an overcurrent flowing through a main transistor of a switching regulator. The overcurrent detecting circuit includes a selector that outputs a drain voltage or a source voltage of the main transistor according to the on or off state of the main transistor, a reference voltage circuit that outputs a voltage, which is the product of the on-state resistance of a comparison transistor having a gate to which a gate voltage when the main transistor is turned on is applied and a current from a constant current source, and a comparison circuit that compares the output of the selector with the output of the reference voltage circuit.

In the comparison circuit of the overcurrent detecting circuit, variable resistors individually generate a current in accordance with the output of the selector and a current in accordance with the output of the reference voltage circuit, and a current mirror circuit compares the generated currents.

In the technique disclosed in JP-A No. 2007-244128, an overcurrent flowing through the main transistor is detected by the comparison between the drain voltage of the main transistor and the drain voltage of the comparison transistor based on a ground level. Therefore, when the main transistor is operated by the bootstrap, the overcurrent necessarily is accurately detected.

### INTRODUCTION TO THE INVENTION

The present disclosure has been made in view of the above circumstances and provides an overcurrent detecting circuit and a power supply device.

According to an aspect of the disclosure, there is provided an overcurrent detecting circuit including: a comparison transistor which includes a gate and a drain respectively connected to a gate and a drain of a main transistor provided in a power circuit and which is used for comparison with the main transistor when a voltage higher than a power supply voltage generated by the power circuit is applied to the gate of the main transistor and the gate of the comparison transistor during an operation of the power circuit; a constant current source circuit which generates a constant current based on a predetermined reference voltage during the operation of the power circuit and which supplies a constant current to the comparison transistor; and a comparison circuit which compares a source voltage of the comparison transistor with a source voltage of the main transistor during the operation of the power circuit and which outputs a voltage indicating the comparison result.

### BRIEF DESCRIPTION OF THE DRAWINGS

Exemplary embodiments of the present disclosure will be described in detail based on the following figures, wherein:

FIG. 1 is a circuit diagram (partial block diagram) illustrating the structure of a power supply device according to a first exemplary embodiment;

FIG. 2 is a flowchart illustrating the flow of the process of an overcurrent detection control program according to the first exemplary embodiment;

FIG. 3 is a circuit diagram (partial block diagram) illustrating the structure of a power supply device according to a second exemplary embodiment; and

FIG. 4 is a circuit diagram (partial block diagram) illustrating the structure of a power supply device according to a third exemplary embodiment.

### DETAILED DESCRIPTION

The exemplary embodiments of the present disclosure are described and illustrated below to encompass an overcurrent detecting circuit and a power supply device and, more particularly, to an overcurrent detecting circuit, that detects an overcurrent flowing through a main transistor of a power circuit and a power supply device including the overcurrent detecting circuit. Of course, it will be apparent to those of ordinary skill in the art that the preferred embodiments discussed below are exemplary in nature and maybe reconfigured without departing from the scope and spirit of the present disclosure. However, for clarify and precision, the exemplary embodiments as discussed below may include optional steps, methods, and features that one of ordinary skill should recognize as not being a requisite to fall within the scope of the present disclosure. Hereinafter, an exemplary embodiment of the present disclosure will he described in detail with reference to the drawings.

### First Exemplary Embodiment

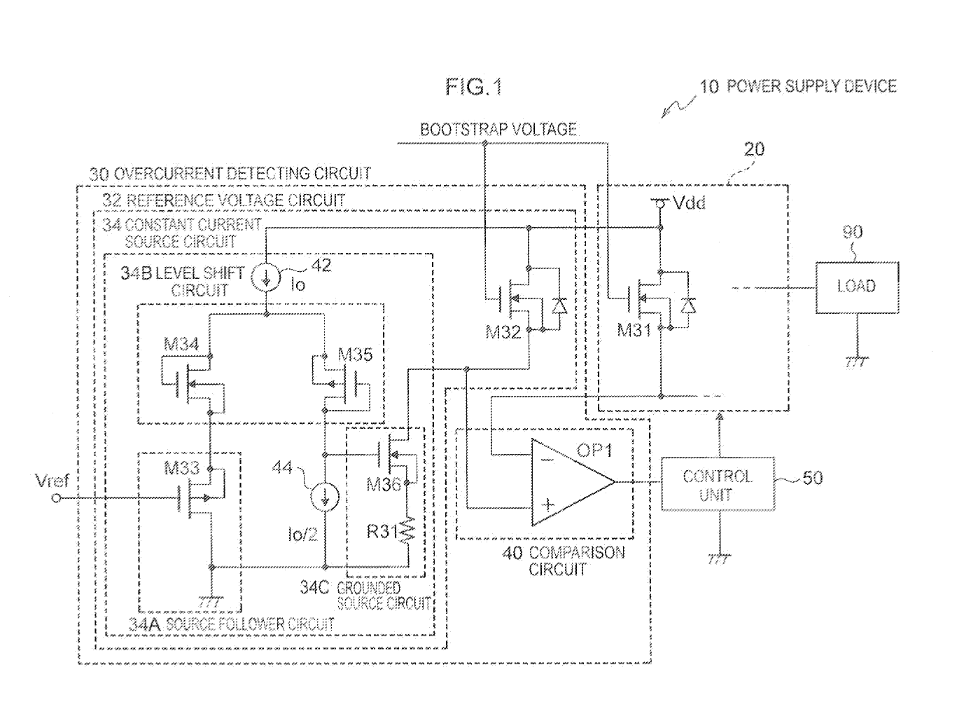

FIG. 1 is a diagram illustrating the structure of a power supply device 10 according to an exemplary embodiment.

As shown in FIG. 1, the power supply device 10 according to this exemplary embodiment includes a power circuit 20, an overcurrent detecting circuit 30, and a control unit 50. The power circuit 20 is a switching regulator. The overcurrent detecting circuit 30 is provided in the power circuit 20 and detects an overcurrent flowing through a main transistor M31 which is an NMOS transistor. The control unit 50 controls the overall operation of the power supply device 10.

The power circuit 20 generates power supplied to a load 90 by the operation of the main transistor M31. The power circuit 20 according to this exemplary embodiment is a switching regulator in which the main transistor M31 is operated by a bootstrap. A step-up switching regulator or a step-down switching regulator may be applied to the power circuit 20.

A power supply voltage V_{dd} generated by the power circuit 20 is applied to a drain of the main transistor M31. A source of the main transistor M31 is connected to another element of the power circuit 20. Since a known power circuit is used as the power circuit 20 according to this exemplary embodiment, the detailed circuit structure of the power circuit 20 is not shown.

The overcurrent detecting circuit 30 according to this exemplary embodiment includes a reference voltage circuit 32 and a comparison circuit 40. The reference voltage circuit 32 according to this exemplary embodiment includes a constant current source circuit 34 and a comparison transistor M32 which is an NMOS transistor. The constant current source circuit 34 according to this exemplary embodiment includes a source follower circuit 34A, a level shift circuit 34B, a grounded source circuit 34C, and two constant current sources 42 and 44.

The source follower circuit 34A includes a PMOS transistor (hereinafter, referred to as a “transistor”) M33. A predetermined reference voltage V_{ref} is applied to a gate of the transistor M33 and a source of the transistor M33 is connected to the ground. In the power supply device 10 according to this exemplary embodiment, a band gap reference voltage source is used as a voltage-source of the reference voltage V_{ref}, but the disclosure is not limited thereto. For example, other reference voltage sources, such as a reference voltage source formed by combining a depression-type MOS transistor and an NMOS transistor, may be used.

The level shift circuit 34B includes plural (in this exemplary embodiment, two) MOS transistors (hereinafter, referred to as “transistors”) M34 and M35 each of which includes a gate and a drain connected to each other and serves as a diode. The drain of the transistor M34 is connected to the source of the transistor M35, and the power supply voltage V_{dd} is applied to a connection line therebetween through the constant current source 42. The source of the transistor M34 is connected to the drain of the transistor M33. The drain of the transistor M35 is connected to the ground through the constant current source 44. The constant current source 42 and the constant current source 44 are configured such that the constant current source 44 supplies a current (I₀/2) corresponding to half of the current I₀ supplied by the constant current source 42.

The grounded source circuit 34C includes an NMOS transistor (hereinafter, referred to as a “transistor”) M36 and a resistor R31. A gate of the transistor M36 is connected to a connection line between the transistor M35 and the constant current source 44, and a source of the transistor M36 is connected to the ground through the resistor 31.

The comparison transistor M32 and the main transistor M31 according to this exemplary embodiment are manufactured by the same process. A drain of the transistor M36 is connected to a source of the comparison transistor M32. Therefore, the value of the current flowing through the comparison transistor M32 is defined by the resistance value of the resistor R31.

The gate of the main transistor M31 and the gate of the comparison transistor M32 are connected to each other. The gate of the main transistor M31 and the gate of the comparison transistor M32 are turned on all the time by the main transistor M31 and the comparison transistor M32 and a bootstrap voltage whose on-state resistance does not vary is applied to the gate of the main transistor M31 and the gate of the comparison transistor M32. The main transistor M31 and comparison transistor M32 have drains connected to each other and the power supply voltage V_{dd} is applied to the drains.

The comparison circuit 40 includes a comparator OP1 which is an operational amplifier (hereinafter, referred to as an “op amp”). The source of the main transistor M31 is connected to an inverting input terminal of the comparator OP1, and the source of the comparison transistor M32 is connected to a non-inverting input terminal of the comparator OP1. An output terminal of the comparator OP1 is connected to the control unit 50. The power circuit 20 is connected to the control unit 50. The operation of the power circuit 20 is controlled by the control unit 50.

As the operation of the power supply device 10 according to this exemplary embodiment, the operation of the overcurrent detecting circuit 30 according to the disclosure will be described.

In the source follower circuit 34A, the reference voltage V_{ref} is applied from the band gap reference voltage source to the gate of the transistor M33. The reference voltage V_{ref} is applied to the transistor M36 of the grounded source circuit 34C through the level shift circuit 34B. Therefore, an output current I from the transistor M36 is represented by the following Equation 1 using the resistance value R₃₁ of the resistor R31 connected to the source of the transistor M36. Equation 1 is established when the transistor M34 and the transistor M36 have the same dimensions and the same current (I₀/2) flows through the transistor M34 and the transistor M36. In this case, the voltage between the gate and the source of the transistor M34 is equal to the voltage between the gate and the source of the transistor M36.

$$I = \frac{{V}_{ref}}{{R}_{33}} \qquad Equation ( 1 )$$

In the power supply device 10 according to this exemplary embodiment, a gate-source voltage which is possible to turn on the gate of the comparison transistor M32 and the gate of the main transistor M31 on all the time, that is, a voltage that is three to four times more than the threshold voltages of the transistors is applied to the gate of each of the comparison transistor M32 and the main transistor M31. In this state, both the comparison transistor M32 and the main transistor M31 are operated in a non-saturated region, that is, an on-state resistance region.

In the power supply device 10 according to this exemplary embodiment, the areas of the comparison transistor M32 and the main transistor M31 are adjusted such that the on-state resistance ratio of the main transistor M31 to the comparison transistor M32 is n (n is a real number other than 0 (zero)). Then, the transistors M32 and M31 are laid out.

The output current I (=V_{ref}/R₃₁) is supplied to the comparison transistor M32. Assuming of an overcurrent state, when a current value when the overcurrent is detected is Iₗᵢₘᵢₜ, the current, value Iₗᵢₘᵢₜ flows to the main transistor M31. The source voltage of the comparison transistor M32 and the source voltage of the main transistor M31 are applied to the comparator OP1 and then compared by the comparator OP1.

When the on-state resistance of the main transistor M31 is Rₒₙ, the on-state resistance of the comparison transistor M32 is n×Rₒₙ. Therefore, when, the overcurrent is detected, the current Iₗᵢₘᵢₜ is represented by the following Equation 3.

$$\begin{matrix}{R}_{int} \cdot {I}_{limit} - n \cdot {r}_{oft} \times \frac{{V}_{ref}}{{R}_{31}} & Equation ( 2 ) \\ {I}_{limit} = n \times \frac{{V}_{ref}}{{R}_{33}} & Equation ( 3 )\end{matrix}$$

In Equations 2and 3, n is a constant value, V_{ref} indicates a reference voltage, and the current Iₗᵢₘᵢₜ is determined by the resistance value of the resistor R31. Therefore, when the resistor R31 is configured with an element whose temperature dependence is low, it is possible to detect an overcurrent with a small variation.

As such, the overcurrent flowing through the main transistor M31 can be represented by the product of the current I(=V_{ref}/R₃₁) flowing through the comparison transistor M32 and the ratio of the on-state resistance Rₒₙ of the main transistor M31 to the on-state resistance (=n×Rₒₙ) of the comparison transistor M32. Therefore, when the resistor R31 is configured of an element whose temperature dependence is low, it is possible to accurately detect an overcurrent flowing through the main transistor M31 that is operated by the bootstrap.

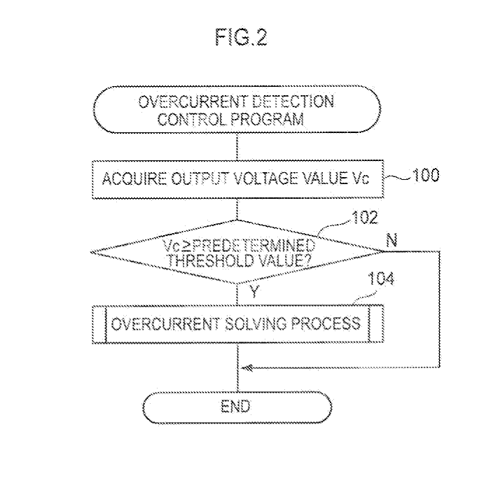

The operation of the control unit 50 will be described with reference to FIG. 2. FIG. 2 is a flowchart illustrating the flow of the process of an overcurrent detection control program executed by the control unit 50 at a predetermined time interval (in this exemplary embodiment, at an interval of 1 second) when the power supply device 10 is operated. The program is stored in a memory (not shown) provided in the control unit 50 in advance.

In the flowchart shown in FIG. 2, in Step 100, a voltage value (hereinafter, referred to as an “output voltage value”) V_{c} applied from the output terminal of the comparator OP1 is acquired. In Step 102, it is determined whether the acquired output voltage value V_{c} is a predetermined threshold value or more. The predetermined threshold value is set as a lower limit of the output voltage value of the comparator OP1 when the voltage (the source voltage of the main transistor M31) applied to the inverting input terminal is higher than the voltage (the source voltage of the comparison transistor M32) applied to the non-inverting input terminal. When the determination result is negative (No), the overcurrent detection control program ends. When the determination result is affirmative (Yes), the process proceeds to Step 104.

In Step 104, a predetermined process, which is set as solving process when the overcurrent flowing through the main transistor M31 is detected (hereinafter, referred to as an “overcurrent solving process”), is performed, and then the overcurrent detection control program ends. In the overcurrent detection control program according to this exemplary embodiment, a process of stopping the application of a voltage to the gate of the main transistor M31 is performed as the overeurrent solving process, but the disclosure is not limited thereto. For example, any one of the following processes or combinations thereof which suppress defects caused by the overcurrent may be used in addition to the above-mentioned processes; a process of reducing the level of the voltage applied to the gate of the main transistor M31 by a predetermined value; a process of stopping the application of the power supply voltage V_{dd} to the drain of the main transistor M31; and a process of shutting down a power supply path from the power circuit 20 to the load 90 and etc.

As described above, in this exemplary embodiment, the gate and the drain of the comparison transistor used tor comparison with the main transistor are connected to the gate and the drain of the main transistor, respectively, and a constant current flows to the comparison transistor. Therefore, voltage levels which are reference for the drain voltage of the comparison transistor and the drain voltage of the main transistor can be common, and it is possible to operate the comparison transistor in a preferred state. As a result, it is possible to accurately detect an overcurrent even when the main transistor is operated by the bootstrap.

In this exemplary embodiment, the constant current source circuit includes the source follower circuit mat outputs a voltage corresponding to the reference voltage and the grounded source circuit that generates the constant current based on the voltage output from the source follower circuit. Therefore, it is possible to form the constant current source circuit with a circuit which can be available in general. As a result, it is possible to reduce manufacturing the cost and simplify the structure of the constant current source circuit.

In particular, in this exemplary embodiment, the constant current source circuit further includes the level shift circuit that is provided between the source follower circuit and the grounded source circuit. Therefore, it is possible to accurately set the value of the constant current generated by the constant current source circuit to a current value in accordance with the reference voltage.

In this exemplary embodiment, the comparison transistor and the main transistor are manufactured by the same process. Therefore, it is possible to detect an overcurrent more accurately.

In this exemplary embodiment, the operation of the power circuit is controlled based on the detection result of the overcurrent detecting circuit. Therefore, it is possible to prevent the occurrence of defects due to an overcurrent in advance.

### Second Exemplary Embodiment

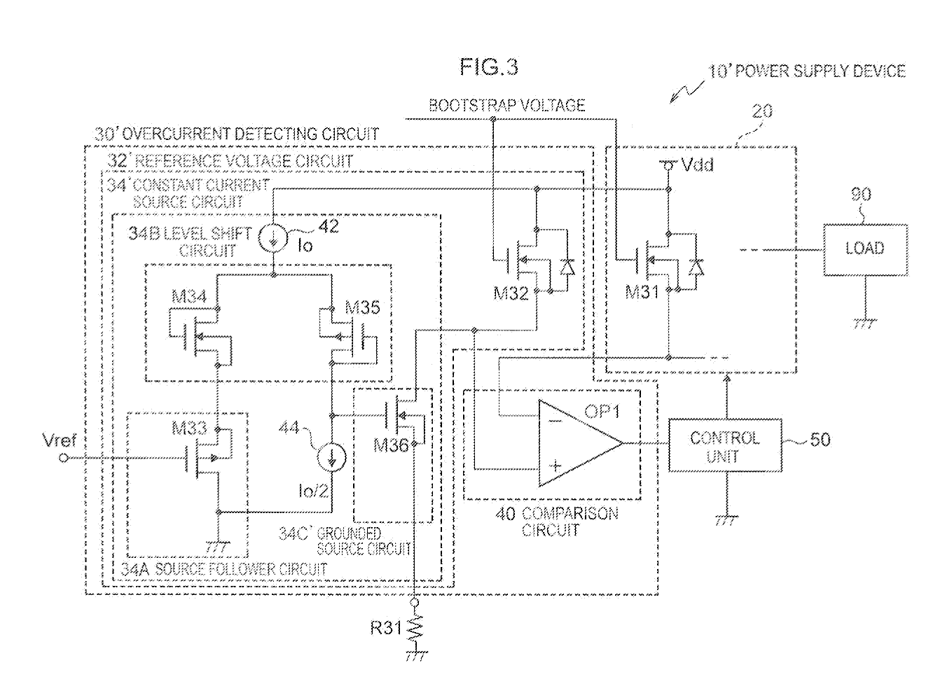

The structure of a power supply device 10′ according to a second exemplary embodiment will be described with reference to FIG. 3. In FIG. 3, the same components as those in FIG. 1 are denoted by the same reference numerals as those shown in FIG. 1 and a description thereof will be omitted.

As shown in FIG. 3, the power supply device 10′ according to the second exemplary embodiment differs from the power supply device 10 according to the first exemplary embodiment in the following points: an overcurrent detecting circuit 30′ is an integrated circuit; and the resistor R31 is provided outside the integrated circuit.

As such, in the second exemplary embodiment the overcurrent detecting circuit is an integrated circuit and a resistor (resistor R31) for setting the current value of the constant current generated by the constant current source circuit is provided outside the integrated circuit in the constant current source circuit. Therefore, it is possible to avoid the trimming of the integrated circuit in addition to the effects of the first exemplary embodiment.

### Third Exemplary Embodiment

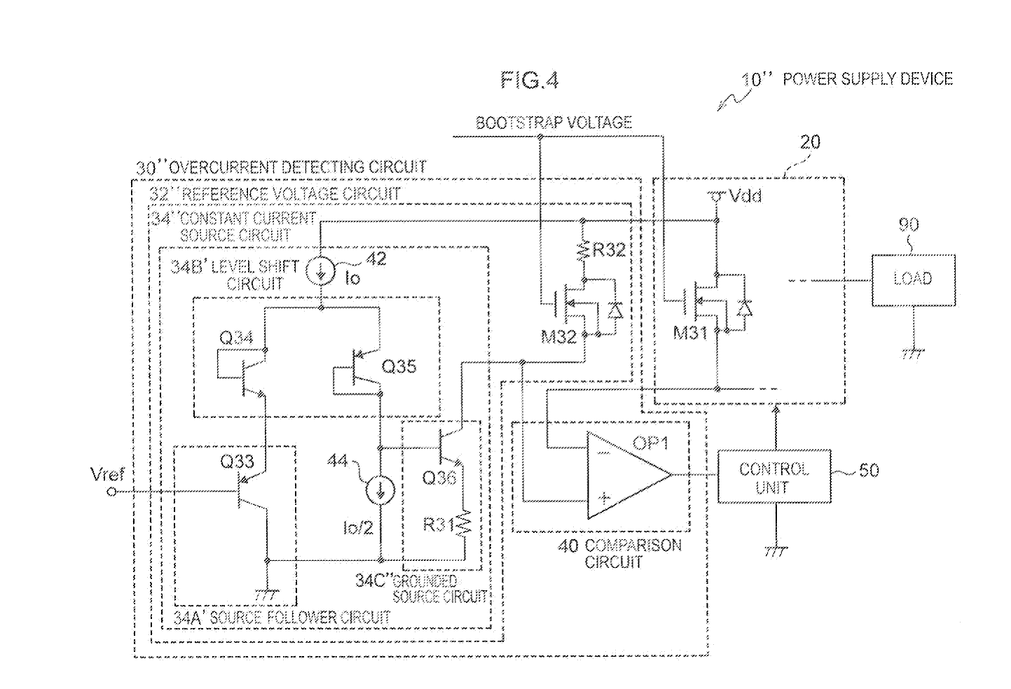

The structure of a power supply device 10′ according to a third exemplary embodiment will be described with reference to FIG. 4. In FIG. 4, the same components as those in FIG. 1 are denoted by the same reference numerals as those shown in FIG. 1 and a description thereof will be omitted.

As shown in FIG. 4, the power supply device 10″ according to the third exemplary embodiment differs from the power supply device 10 according to the first exemplary embodiment in the following points: bipolar transistors Q33 to Q36 are used instead of the transistors M33 to M36, that is, an emitter follower circuit 34A′ is used instead of the source follower circuit 34A; a level shift circuit 34B′ which is configured of a bipolar transistor is used instead of the level shift circuit 34B which is configured of a field effect, transistor; and an grounded emitter circuit 34C″ is used instead of the grounded source circuit 34C; and a resistor R32 is connected to the drain of the comparison transistor M32.

In the power supply device 10″ according to this exemplary embodiment, the resistance value R₃₂ of the resistance value R32 is adjusted in advance such that the sum of the resistance value R₃₂ of the resistor R32 and the on-state resistance of the comparison transistor M32 is equal to the on-state resistance of the main transistor M31.

In the power supply device 10″ according to this exemplary embodiment, the current value Iₗᵢₘᵢₜ when an overcurrent is detected is represented by the following Equation 4.

$${I}_{limit} = n \times \frac{{V}_{ref}}{{R}_{31}} + \frac{{R}_{32}}{{R}_{31}} \times \frac{{V}_{ref}}{{R}_{on}} \qquad Equation ( 4 )$$

In the first term of Equation 4, n indicates the area ratio of the transistor M32 to the transistor M31 and n does not have temperature dependence and power supply voltage dependence. V_{ref} indicates a reference voltage without temperature dependence. Therefore, in the first term, the resistor R31 which is configured of an element whose temperature dependence is low, and thus it is possible to perform setting the resistance with a small variation.

In the second term of Equation 4, R₃₂/R₃₁ indicates the ratio of the resistance value of the resistor R32 to the resistance value of the resistor R31 and varies a little. Rₒₙ indicates the on-state resistance of the main transistor M31 and varies a little. Therefore, the second term is affected by the on-state resistance.

As such, in Equation 4, the variation is caused by two factors: the resistance value R₃₁ of the resistor R31; and the on-state resistance Rₒₙ of the main transistor M31. The detection, accuracy of the current Iₗᵢₘᵢₜ is determined by the above two values.

In the overcurrent detecting circuit 30″ according to the third exemplary embodiment, it is possible to detect an overcurrent with relatively high accuracy which is less than that of the overcurrent detecting circuit 30 according to the first exemplary embodiment.

As such, in the third exemplary embodiment, a resistor is connected to the drain of the comparison transistor. Therefore, it is possible to adjust the resistance values such that the sum of the resistance value of the resistor and the on-state resistance of the comparison transistor is equal to the on-state resistance of the main transistor, in addition to the effects of the first exemplary embodiment. As a result, even when the absolute values of the on-state resistance of the comparison transistor and the on-state resistance of the main transistor vary greatly, it is possible to accurately detect an overcurrent.

In the exemplary embodiments, the bootstrap voltage is applied to the gate of the main transistor M31, but the disclosure is not limited thereto. For example, a charge pump voltage can be applied to the gate of the main transistor M31. In this case, the power circuit 20 needs to be a charge pump type. According to this structure, it is possible to obtain the same effects as those in the exemplary embodiments.

In the exemplary embodiments, the comparator OP1 is used in the comparison circuit 40 as an op amp, but the disclosure is not limited thereto. An op amp serving as an amplifier may be used in the comparison circuit 40. In this case, the op amp amplifies the difference between the voltage applied to the non-inverting input terminal and the voltage applied to inverting input terminal and outputs the amplified voltage. Therefore, it is possible to perform various kinds of processes using the output.

The structures of the power supply devices 10, 10′, and 10″ (see FIGS. 1, 3, and 4) according to the exemplary embodiments are just illustrative. An unnecessary component may be removed, a new component may be added, or the arrangement positions of the components may be changed without departing from the scope and spirit of the disclosure.

According to a first aspect of the disclosure, there is provided an overcurrent detecting circuit including: a comparison transistor which includes a gate and a drain respectively connected to a gate and a drain of a main transistor provided in a power circuit and which is used for comparison with the main transistor when a voltage higher than a power supply voltage generated by the power circuit is applied to the gate of the main transistor and the gate of the comparison transistor during an operation of the power circuit; a constant current source circuit which generates a constant current based on a predetermined reference voltage during the operation of the power circuit and which supplies a constant current to the comparison transistor; and a comparison circuit which compares a source voltage of the comparison transistor with a source voltage of the main transistor during the operation of the power circuit and which outputs a voltage indicating the comparison result.

According to the overcurrent detecting circuit of the first aspect, the gate and the drain of the comparison transistor used for comparison with the main transistor provided in the power circuit are connected to the gate and the drain of the main transistor, respectively, and a voltage that is higher than the power supply voltage generated by the power circuit is applied to the gate during the operation of the power circuit. In this way, the main transistor is operated by the bootstrap.

During the operation of the power circuit, the constant current source circuit generates a constant current based on a predetermined reference voltage and supplies the constant current to the comparison transistor. The comparison circuit compares the source voltage of the comparison transistor with the source voltage of the main transistor and outputs a voltage indicating the comparison result.

As such, according to the overcurrent detecting circuit of the first aspect, the gate and the drain of the comparison transistor used for comparison with the main transistor are connected to the gate and the drain of the main transistor, respectively, and a constant current flows to the comparison transistor. Therefore, voltage levels which are reference for the drain, voltage of the comparison transistor and the drain voltage of the main transistor can be common, and it is possible to operate the comparison transistor in a preferred state. As a result, it is possible to accurately detect an overcurrent even when the main transistor is operated by the bootstrap.

According to a second aspect of the disclosure, in the first aspect, the constant current source circuit may include: a source follower circuit which outputs a voltage in accordance with the reference voltage; and a grounded source circuit which generates the constant current based on the voltage output from the source follower circuit. In this way, it is possible to configure the constant current source circuit according to the disclosure with a circuit which can be available in general. As a result, it is possible to reduce manufacturing costs and simplify the structure of die constant current source circuit.

According to a third aspect of the disclosure, in the second aspect, the constant current source circuit further may include a level shift circuit which is provided between the source follower circuit and the grounded, source circuit. In this way, it is possible to accurately set the current value of the constant current generated by the constant current source circuit to a current value in accordance with the reference voltage.

According to a fourth aspect of the disclosure, in the first aspect, the constant current source circuit may include: an emitter follower circuit which outputs a voltage in accordance with the reference voltage; and a grounded emitter circuit which generates the constant current based on the voltage output from the emitter follower circuit. In this way, it is possible to configure the constant current source circuit according to the disclosure with a circuit which can be available in general. As a result, it is possible to reduce manufacturing costs and simplify the structure of the constant current source circuit.

According to a filth aspect of the disclosure, in the fourth aspect, the constant current source circuit may further include a level shift circuit which is provided between the emitter follower circuit and the grounded emitter circuit. In this way, it is possible to accurately set the current value of the constant current generated by the constant current source circuit to a current value in accordance with the reference voltage.

According to a sixth aspect of the disclosure, the comparison transistor and the main transistor may be manufactured by the same process. In this way, it is possible to detect an overcurrent more accurately.

According to a seventh aspect of the disclosure, the overcurrent detecting circuit may be an integrated circuit, and the constant current source circuit may include a resistor which is provided outside the integrated circuit and which sets a current value of the constant current generated by the constant current source circuit. In this way, it is possible to avoid performing trimming with respect to an integrated circuit when the overcurrent detecting circuit is the integrated circuit.

According to an eighth aspect of the disclosure, the overcurrent detecting may further include a resistor which is connected to the drain of the comparison transistor. In this way, it is possible to adjust the resistance values such that the sum of the resistance value of the resistor and the on-state resistance of the comparison transistor is equal to the on-state resistance of the main transistor. As a result, even when the absolute values of the on-state resistance of the comparison transistor and the on-state resistance of the main transistor vary greatly, it is possible to accurately detect an overcurrent.

According to a ninth aspect of the disclosure, there is provided a power supply device including: a power circuit which includes: a main transistor whose overcurrent is detected by an overcurrent detecting circuit; and the overcurrent defecting circuit which includes: a comparison transistor which comprises a gate and a drain respectively connected to a gate and a drain of the main transistor and which is used for comparison with the main transistor when a voltage higher than a power supply voltage generated by the power circuit is applied to the gate of the main transistor and the gate of the comparison transistor during an operation of the power circuit; a constant current source circuit which generates a constant current based on a predetermined reference voltage during the operation of the power circuit and which supplies a constant current to the comparison transistor; and a comparison circuit which compares a source voltage of the comparison transistor with a source voltage of the main transistor during the operation of the power circuit and which outputs a voltage indicating the comparison result.

The power supply device according to the ninth aspect includes the overcurrent detecting circuit according to the disclosure. Therefore, similar to the overcurrent detecting circuit, even when the main transistor is operated by the bootstrap, it is possible to accurately detect an overcurrent.

According to a tenth aspect of the disclosure, in the ninth aspect, the power supply device may further include a control unit which controls the operation of the power circuit based on the detection result of the overcurrent detecting circuit, in this way, it is possible to prevent the occurrence of defects due to an overcurrent in advance.

In the ninth aspect, the power supply device may include the overcurrent detecting circuit according to any one of the second to eighth aspects.

Although the exemplary embodiments of the disclosure have been described above, the technical scope of the disclosure is not limited to the range of the exemplary embodiments. Various modifications and changes of the disclosure can be made without departing from the scope and spirit of the invention, and the modifications and changes are also included in the technical scope of the invention.

The exemplary embodiments do not limit the invention described in the claims, and all combinations of the components according to the exemplary embodiments are not indispensable to the solving means of the invention. Structures in various stages are included in the above-described exemplary embodiments and plural components according to the above-described exemplary embodiments may be appropriately combined with each other to form various structures of the invention. Some of the components according to the above-described exemplary embodiments maybe removed as long as the same effects as described above can be obtained.

Following from the above description and embodiment, it should be apparent to those of ordinary skill in the art that, while the foregoing constitute exemplary embodiments of the present disclosure, the disclosure is not necessarily limited to these precise embodiments and that changes may be made to these embodiments without departing from the scope of the invention as defined by the claims. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet, any or all of the identified advantages or objects of the disclosure discussed herein in order to fall within the scope of any claims, since the invention is defined by the claims and since inherent and/or unforeseen advantages of the present disclosure may exist even though they may not have been explicitly discussed herein.

What is claimed is:

1. All overcurrent detecting circuit comprising:
a comparison transistor which includes a gate and a drain respectively connected to a gate and a drain of a main transistor provided in a power circuit and which is used for comparison with the main transistor when a voltage higher than a power supply voltage generated by the power circuit is applied to the gate of the main transistor and the gate of the comparison transistor during an operation of the power circuit;
a constant current source circuit which generates a constant current based on a predetermined reference voltage during the operation of the power circuit and which supplies a constant current to the comparison transistor; and
a comparison circuit which compares a source voltage of the comparison transistor with a source voltage of the main transistor during the operation of the power circuit and which outputs a voltage indicating the comparison result.

2. The overcurrent detecting circuit of claim 1, wherein the constant current source circuit comprises:
a source follower circuit which outputs a voltage in accordance with the reference voltage; and
a grounded source circuit which generates the constant current based on the voltage output from the source follower circuit.

3. The overcurrent detecting circuit of claim 2, wherein the constant current source circuit further comprises a level shift circuit which is provided between the source follower circuit and the grounded source circuit.

4. The overcurrent detecting circuit of claim 1, wherein the constant, current source circuit comprises:
an emitter follower circuit which outputs a voltage in accordance with the reference voltage; and
a grounded emitter circuit which generates the constant current based on the voltage output from the emitter follower circuit.

5. The overcurrent detecting circuit of claim 4, wherein the constant current source circuit further comprises a level shift circuit which is provided between the emitter follower circuit and the grounded emitter circuit.

6. The overcurrent detecting circuit of claim 1, wherein the comparison transistor and the main transistor are manufactured by the same process.

7. The overcurrent detecting circuit of claim 1, wherein the overcurrent detecting circuit is an integrated circuit, and
the constant current source circuit comprises a resistor which is provided outside the integrated circuit and which sets a current value of the constant current generated by the constant current source circuit.

8. The overcurrent detecting circuit of claim 1, further comprising: a resistor which is connected to the drain of the comparison transistor.

9. A power supply device comprising:
a power circuit comprising:
a main transistor whose overcurrent is detected by an overcurrent detecting circuit; and
the overcurrent detecting circuit comprising:
a comparison transistor which comprises a gate and a drain respectively connected to a gate and a drain of the main transistor and which is used for comparison with the main transistor when a voltage higher than a power supply voltage generated by the power circuit is applied to the gate of the main transistor and the gate of the comparison transistor during an operation of the power circuit;
a constant current source circuit which generates a constant current based on a predetermined reference voltage during the operation of the power circuit and which supplies a constant current to the comparison transistor; and
a comparison circuit which compares a source voltage of the comparison transistor with a source voltage of the main transistor during the operation of the power circuit and which outputs a voltage indicating the comparison result.

10. The power supply device of claim 9 further comprising a control unit which controls the operation of the power circuit based on the detection result of the overcurrent detecting circuit.

11. The power supply device of claim 9, wherein the constant current source circuit comprises:
a source follower circuit which outputs a voltage in accordance with the reference voltage; and
a grounded source circuit which generates the constant current based on the voltage output from the source follower circuit.

12. The power supply device of claim 11, wherein the constant current source circuit further comprises a level shift circuit which is provided between the source follower circuit and the grounded source circuit.

13. The power supply device of claim 9, wherein the constant current source circuit comprises:
an emitter follower circuit which outputs a voltage in accordance with the reference voltage; and
a grounded emitter circuit which generates the constant current based on the voltage output from the emitter follower circuit.

14. The power supply device of claim 13, wherein the constant current source circuit further comprises a level shift circuit which is provided between the emitter follower circuit and the grounded emitter circuit.

15. The power supply device of claim 9, wherein the comparison transistor and the main transistor are manufactured by the same process.

16. The power supply device of claim 9, wherein the overcurrent detecting circuit is an integrated circuit, and
the constant current source circuit comprises a resistor which is provided outside the integrated circuit and which sets a current value of the constant current generated by the constant current source circuit.

17. The power supply device of claim 9, wherein the overcurrent detecting circuit further comprises a resistor which is connected to the drain of the comparison transistor.
